(19) United States
(12) Patent Application Publication
(10) Pub. No.: US 2005/0073878 A1
(43) Pub. Date: Apr. 7, 2005

(54) Multi-sensing level MRAM structure with different magnetoresistance ratios

(75) Inventors: Wen Chin Lin, Hsin-Chu (TW); Denny D. Tang, Saratoga, CA (US)

Correspondence Address: HAYNES AND BOONE, LLP, 901 MAIN STREET, SUITE 3100, DALLAS, TX, 75202, US

(73) Assignee: Taiwan Semiconductor Manufacturing Co., Ltd., Hsin-Chu (TW)

(21) Appl. No.: 10/678,699

(22) Filed: Oct. 3, 2003

(51) Int. Cl. G11C 11/15

(52) U.S. Cl. 365/158; 365/173; 365/171

(57) ABSTRACT

A new process and structure for a multi-sensing level magnetic random access memory (MRAM) cell having different magneto-resistance (MR) ratios includes an improved magnetic tunnel junction (MTJ) configuration. The MTJ configuration includes a first free layer proximate to a first tunneling barrier and a second free layer proximate to a second tunneling barrier and a pinned layer. The first free layer is sandwiched between the first and second tunneling layers. The first tunneling barrier has a MR ratio that differs from a MR ratio of the second tunneling barrier.

### BACKGROUND

The present disclosure relates generally to the field of nonvolatile memory devices, and more specifically to a multiple level sensing magnetic tunnel junction (MTJ) memory cell devices.

The relentless demand for evermore compact, portable, and low cost consumer electronic products has driven electronics manufacturers to develop and manufacture nonvolatile, high density electronic storage devices having low power consumption, increased storage capacity, and a low cost. Nonvolatile memory devices are desirable in these applications because the stored data can be easily preserved. In some nonvolatile memory devices, the data is preserved even when a power supply is exhausted or disconnected from the memory device. Other nonvolatile memory devices may require continuous power, but do not require refreshing of the data. Low power consumption may also be desirable because smaller power sources can be used, reducing the size of consumer electronic devices. To meet these requirements, manufacturers have begun to utilize magnetic random access memory (MRAM) as one solution that meets the requirements of many consumer electronic applications.

The present disclosure relates to MRAM based on a magnetic tunnel junction (MTJ) cell. An MTJ configuration can be made up of three basic layers, a “free” ferromagnetic layer, an insulating tunneling barrier, and a “pinned” ferromagnetic layer. In the free layer, the magnetization moments are free to rotate under an external magnetic field, but the magnetic moments in the “pinned” layer cannot. The pinned layer can be composed of a ferromagnetic layer and/or an anti-ferromagnetic layer which “pins” the magnetic moments in the ferromagnetic layer. A very thin insulation layer forms the tunneling barrier between the pinned and free magnetic layers. In order to sense states in the MTJ configuration, a constant current can be applied through the cell. As the magneto-resistance varies according to the state stored in the cell, the voltage can be sensed over the memory cell. To write or change the state in the memory cell, an external magnetic field can be applied that is sufficient to completely switch the direction of the magnetic moments of the free magnetic layers.

MTJ configurations often employ the Tunneling Magneto-Resistance (TMR) effect, which allows magnetic moments to quickly switch the directions in the magnetic layer by an application of an external magnetic field. Magneto-resistance (MR) is a measure of the ease with which electrons may flow through the free layer, tunneling barrier, and the pinned layer. A minimum MR occurs in an MTJ configuration when the magnetic moments in both magnetic layers have the same direction or are “parallel”. A maximum MR occurs when the magnetic moments of both magnetic layers are in opposite directions or are “anti-parallel.”

### SUMMARY

This disclosure relates to a new process and structure for a multi-sensing level magnetic random access memory (MRAM) cell having different magneto-resistive ratios. In one embodiment, a magnetic tunnel junction (MTJ) configuration is provided for use in the MRAM cell. The MTJ configuration includes a first free layer proximate to a first tunneling barrier and a second free layer proximate to a second tunneling barrier and a pinned layer. The first free layer is sandwiched between the first and second tunneling layers. In some embodiments of the MTJ configuration, the first tunneling barrier has a magneto-resistive (MR) ratio that differs from the a MR ratio of the second tunneling barrier.

In another embodiment, a magnetic memory cell is provided and includes a switching element such as a transistor and a magnetic tunnel junction (MTJ) configuration. The MTJ configuration includes a first MTJ device including a first free layer, a first tunneling barrier, and a first pinned layer and a second MTJ device including a second free layer, a second tunneling barrier, and a second pinned layer. A first conductor connects the first and second MTJ devices and a first magneto-resistive (MR) ratio of the first MTJ device is different from a second MR ratio of the second MTJ device.

In another embodiment, an integrated circuit is provided, including an input/output section, a plurality of logic circuits connected to the input/output section, and a plurality of magnetic memory cells connected to the logic circuits. The magnetic memory cells include a transistor and a storage structure, which further includes a first magnetic junction device including a first free layer, a first tunneling area, and a first pinned layer, a second magnetic junction device including a second free layer, a second tunneling area, and a second pinned layer, and a first conductor connected to configure the first and second magnetic junction devices in parallel. In some embodiments, a first magneto-resistive (MR) ratio of the first magnetic junction device is different from a second MR ratio of the second magnetic junction device.

The foregoing has outlined preferred and alternative features of several embodiments so that those skilled in the art may better understand the detailed description that follows. Additional features will be described below that further form the subject of the claims herein. Those skilled in the art should appreciate that they can readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure.

### BRIEF DESCRIPTION OF THE DRAWINGS

The present disclosure is best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a block diagram of an integrated circuit device having a memory cell array according to one embodiment of the present disclosure.

FIG. 2 is a block diagram of one embodiment of a memory cell for use in the memory cell array of FIG. 1.

FIG. 3 illustrates a cross-sectional view of a first embodiment of a MTJ configuration for use in the memory cell of FIG. 2.

FIG. 4 illustrates a cross-sectional view of a second embodiment of a MTJ configuration for use in the memory cell of FIG. 2.

FIG. 5 illustrates a cross-sectional view of a third embodiment of a MTJ configuration for use in the memory cell of FIG. 2.

FIG. 6 illustrates a cross-sectional view of a fourth embodiment of a MTJ configuration for use in the memory cell of FIG. 2.

FIGS. 7-9 are graphs illustrating hysteresis characteristics of the multiple level sensing MRAM cell shown in FIG. 2.

### DETAILED DESCRIPTION

The present disclosure relates to the field of integrated circuits and nonvolatile memory devices. To illustrate the disclosure, a specific example and configuration of an integrated circuit and memory cell is illustrated and discussed. It is understood, however, that this specific example is only provided to teach the broader inventive concept, and one of ordinary skill in the art can easily apply the teachings of the present disclosure to other magnetic and/or electrical circuits and structures. Also, it is understood that the integrated circuit and memory cell discussed in the present disclosure include many conventional structures formed by conventional processes.

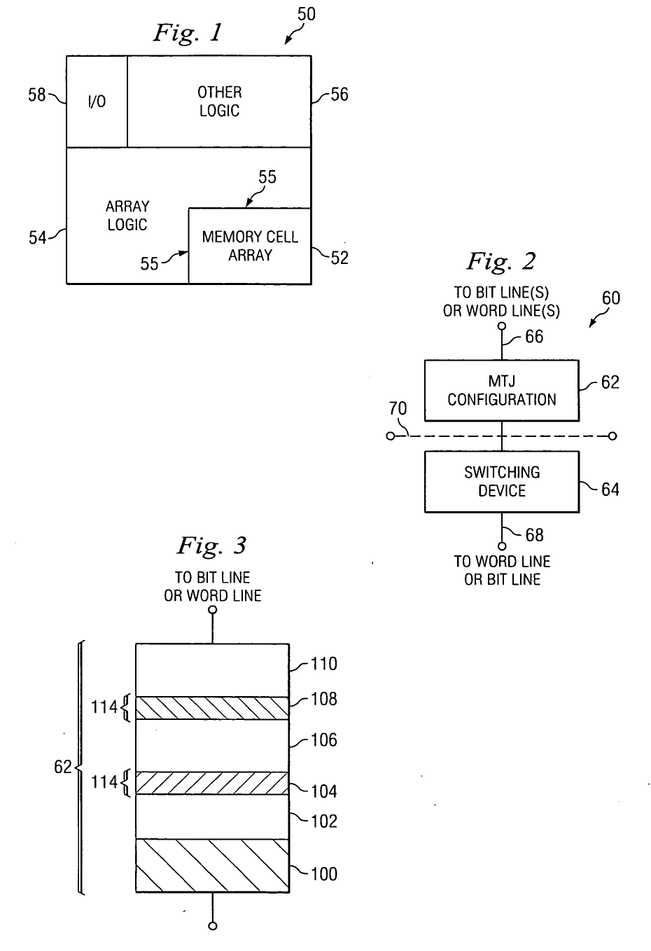

Referring now to FIG. 1 of the drawings, an integrated circuit 50 is one example of a circuit that can benefit from the present disclosure. The integrated circuit 50 includes a memory cell array 52 that can be controlled by an array logic 54 through an interface 55. It is well known in the art that various logic circuitry, such as row and column decoders and sense amplifiers, can be included in the array logic 54, and that the interface 55 may include one or more bit lines, gate lines, digit lines, control lines, word lines, and other communication paths to interconnect the memory cell array 52 with the array logic 54. These communication paths will hereinafter be referred to as bit lines, it being understood that different applications of the present disclosure may use different communication paths. The integrated circuit can further include other logic 56 such as counters, clock circuits, and processing circuits, and input/output circuitry 58 such as buffers and drivers.

Referring to FIG. 2, the memory cell array 52 of FIG. 1 may include one or more magnetic random access memory (MRAM) cells 60. Each MRAM cell 60 does not need to be commonly configured, but for the sake of example, can be generically described as including a configuration of MTJ devices 62 and a switching device 64. Examples of various embodiments of the MTJ configuration 62 are discussed in further detail below, and examples of the switching device 64 include a metal oxide semiconductor (MOS) transistor, a MOS diode, and/or a bipolar transistor. The memory cell 60 can store 1, 2, 3, 4 or more bits, but for the sake of further example, a two bit configuration will be discussed. Also, the present disclosure will focus on the use of single and double junction MTJ devices with different MR ratios, where there can be four magneto-resistance levels. The different MR ratios facilitate the capability of sensing at least four levels of magneto-resistance, and the capacity to store at least two bits.

The MRAM cell 60 includes two terminals, an first terminal 66, a second terminal 68, and a third terminal 70. For the sake of example, the first terminal 66 is connected to one or more bit lines and produces an output voltage in a read operation, which is provided to the bit line(s). The second terminal 68 is connected to one or more word lines, which can activate the cell 60 for a read or write operation. The third terminal 70 may be proximate to a control line, such as a gate or digit line, and can provide a current for producing a magnetic field to effect the MTJ configuration 62. It is understood that the arrangement of bit lines, word lines, control lines, and other communication signals can vary for different circuit designs, and the present discussion is only providing one example of such an arrangement.

Referring to FIG. 3, one embodiment of the MTJ configuration 62 includes two free ferromagnetic layers 106 and 110 and two tunneling barriers 104 and 108 connected in serial to a pinned layer 102 and an anti-ferromagnetic layer 100. The barriers 104 and 108 can be, for example SiOₓ, SiNₓ, SiOₓN_{y}, AlOₓ, TaOₓ, TiOₓ, AlNₓ, or other non-conductive materials. The barriers 104 and 108 can also have different MR ratios. Therefore, barrier 108 can be formed of a different material or a variation of material similar to the other junction 104. The tunneling barriers 104 and 108 can be formed by chemical vapor deposition (CVD), plasma enhanced chemical vapor deposition (PECVD), electro-chemical deposition, physical vapor deposition, molecular manipulation or any other method that is known by one who is skilled in the art. In FIG. 3, the ferromagnetic free layers 106 and 110 can form magnetic junctions 114 with the tunneling barriers 104 and 108. These magnetic junctions 114 can have different MR ratios.

In one example, the MR ratios for barriers 104 and 108 are 60% and 30% respectively (a 2:1 ratio). Thus, for barrier 108, the logical status of 1 has a corresponding magneto-resistance of 1, and the logical status of 0 has a magneto-resistance of 1.3. Similarly, for barrier 104, the logical status of 1 has a corresponding magneto-resistance of 1, and the logical status of 0 has a magneto-resistance of 1.6. The example also assumes that the free layer 106 and free layer 110 are of electrically different materials causing the switching thresholds of the magnetic moment direction to differ. In a high magnetic field, both free layer 106 and layer 110 can align their magnetic moments in the same and parallel direction. In a low magnetic field, only one free layer 106 can change magnetic moment leaving the other free layer undisturbed. Accordingly, the free layers 106 or 110 can be written to further depending upon the location of the control line. The free ferromagnetic layers 106 and 110 could be made from ferromagnetic materials such as, for example, NiFe and NiFeCo, or the free layers 106 and 110 could be comprised of two ferromagnetic layers with a Ru spacer sandwiched there between. The composite free/pinned layer structure is known as a synthetic anti-ferromagnetic structure (SAF). The free or ferromagnetic layers 106 and 110 can be formed by chemical vapor deposition (CVD), plasma enhanced chemical vapor deposition (PECVD), atomic layer deposition (ALD), electrochemical deposition, physical vapor deposition, molecular manipulation or any other method that is known by one who is skilled in the art. The pinned magnetic layer 102 can be an anti-ferromagnetic layer where the magnetic moments are magnetically “pinned” by either an anti-ferromagnetic layer or an anti-ferromagnetic exchange layer placed adjacent to the ferromagnetic material, such as a Ru spacer. Anti-ferromagnetic layers can be also made from materials such as MnFe, IrMnIn or any other suitable anti-ferromagnetic materials. These layers can be formed by chemical vapor deposition (CVD), plasma enhanced chemical vapor deposition (PECVD), ALD, electro-chemical deposition, physical vapor deposition, molecular manipulation or any other method that is known by one who is skilled in the art.

Writing to the multi-sensing level MTJ 62 can be accomplished using a plurality of current paths (e.g., control lines, bit lines, and word lines FIG. 1), which can be orthogonal to each other and cross proximate to the selected MTJ structure 62. Writing to the free layer 106 and 110 can be provided by a plurality of control lines. Current can be supplied to selected control lines wherein an induced magnetic field can change the magnetic moments of the free layer 106 and 110. The control lines may be insulated from the MTJ structure 62 by a dielectric and may be placed at a specific location or distance relative to the MTJ structure 62. The magnitude of the current can depend upon which free layer is selected to be written. Therefore, a low induced current to the control line may provide an induced magnetic filed for the closest free layer, while a larger current can provide an induced magnetic field to the next free layer. Alternatively, the two magnetic junctions 114 in the memory structure 62 can have differing resistance characteristics. The differing resistance characteristics may be realized from materials or process method(s) used to form the different tunneling barriers 104 and 108. MTJ configuration layers tend to decrease in resistance gradually under an applied voltage. Therefore, because the multiple MTJ structure 62 can be comprised of barrier layers 104 and 108 of differing magneto-resistive (MR) ratio, multiple resistance level sensing is possible.

In some cases, a two step writing process may be needed. For example, a large initial current can be supplied that writes free layers 106 and 110, then a smaller current could be supplied that changes the state of the nearest free layer 106 or 110. Alternately, the larger current can be turn into a smaller current reflected opposite of the initial large current injection. This small current reflection reverses the switching field of the smaller free layer 106 or 110. Two step writing can be dedicated to the writing of one free layer 106 or 110 only, without disturbing the other free layer 106 or 110 in the same MTJ structure 62.

Table 1 shows four kinds of conditions for the barrier layers 104 or 108 with different MR ratio structure 62 in FIG. 3. In condition 1 of Table 1, the tunneling resistance can be observed to remain at a minimum while the magnetic moments of both ferromagnetic free layers 106 and 110 and the magnetic moment of the pinned layer 102 are parallel. Under condition 3, larger serial resistances can be realized with both free layers 106 and 110 in parallel but anti-parallel to the magnetic moment of the pinned layer 102. Under condition 2, where the magnetic moments of the free layers 106 and 110 are anti-parallel but free layer 106 is parallel with the pinned layer 102, the serial resistance can be greater than in condition 1. As seen in condition 4, serial resistance can be maximized when the free layers 106 and 110 are anti-parallel and the pinned layer 102 is anti-parallel to free layer 106.

TABLE 1

| | Magnetic Moment Direction | | | |
|---|---|---|---|---|
| | Condition | Condition | Condition | |
| Layer | 1 | 2 | 3 | Condition 4 |
| Free Layer 110 | [symbol] | [symbol] | [symbol] | [symbol] |
| Free Layer 106 | [symbol] | [symbol] | [symbol] | [symbol] |
| Pinned Layer | [symbol] | [symbol] | [symbol] | [symbol] |
| Tunneling Resistance | Minimum | | | |
| Barrier 108 | 1 | 1.3 | 1 | 1.3 |
| (MR ratio 30%) | | | | |
| Barrier 104 | 1 | 1 | 1.6 | 1.6 |
| (MR ratio 60%) | | | | |
| Serial Resistance | 2 | 2.3 | 2.6 | 2.9 |

Turning now toward the reading or sensing function, the MTJ structure 62 with a serial structure has four sensing levels. The binary logical states 0 or 1 of the free layer 106 or free layer 110 can be identified by a multi-level reference circuit included in the array logic 54 (FIG. 1). Since the resistance of the tunnel barrier 104 or 108 varies approximately exponentially to the thickness of the barrier, the electrical current flows generally perpendicular through the barrier 104 or 108. The likelihood of a charge carrier tunneling across the barrier 104 or 108 decreases with the increasing barrier thickness so that the only carriers that tunnel across the junction 114 are those which transverse perpendicular to the junction layer 114. The state of the memory structure 62 can be determined by measuring the resistance of the structure 62 when a read current, much smaller than the write currents, is passed perpendicularly through the MTJ structure 62. The self-field of this read current can be negligible and does not affect the magnetic state of the memory cell. The probability of a charge carrier tunneling across the tunnel barrier 104 or 108 can depend on the relative alignment of the magnetic moments of the free layers 106 or 110. The tunneling current can be spin polarized, which means that the electrical current passing from one of the ferromagnetic layers 106 or 110 to, for example, the pinned layer 102, can be predominantly composed of electrons of one spin type (spin up or spin down) depending on the orientation of the magnetization of the ferromagnetic layer 106 or 110. The degree of the current's spin polarization can be determined by the electronic band structure of the magnetic material composing the ferromagnetic layer 106 or 110 at the interface of the ferromagnetic free layer 106 or 110 with the tunnel barrier 104 or 108. The first ferromagnetic layer 106 thus acts as a spin filter. The probability that the charge carriers can tunnel depends on the availability of electronic states of the same spin polarization as the spin polarization of the electronic current in the second ferromagnetic free layer 110. Usually, when the magnetic moment in the second ferromagnetic layer 110 is aligned to the magnetic moment of the first ferromagnetic layer 106, there are more available electronic states than when the magnetic moment of the second ferromagnetic 110 layer is aligned in opposite direction to that of the first free layer 106. Thus, the tunneling probability of the charge carriers can be high when the magnetic moments of both layers 106 and 110 are aligned, and can be low when the magnetic moments are anti-aligned. Therefore, when the magnetic moments are neither aligned nor anti-aligned, the tunneling probability takes an intermediate value. Thus, the electrical resistance of the MTJ structure 62 depends on both polarization of the electrical current and the electronic states in both of the ferromagnetic layers 106 and 110. As a result, the two possible magnetization directions of the free layers 106 or 110 uniquely define two possible bit states (0 or 1) of the MTJ structure 62.

An MRAM structure for a “stacked” MTJ may consist of multiple layers of magnetic tunneling junctions and ferromagnetic free layers allowing even greater levels of sensing levels to be resolved. For example, in the case of a three junction system with three different MR ratios, eight (2*2*2=8, including 000, 001, 010, 011, 100, 101, 110, 111) levels of sensing levels could be resolved, where each magnetic junction contributes two sensing levels. In this example, there would be three bits in the cell that share the same transistor. The relationship between nₘ, the number of magnetic junctions, and nₛ, the number of magneto-resistance states can be expressed as nₛ=2\hat{ }(nₘ).

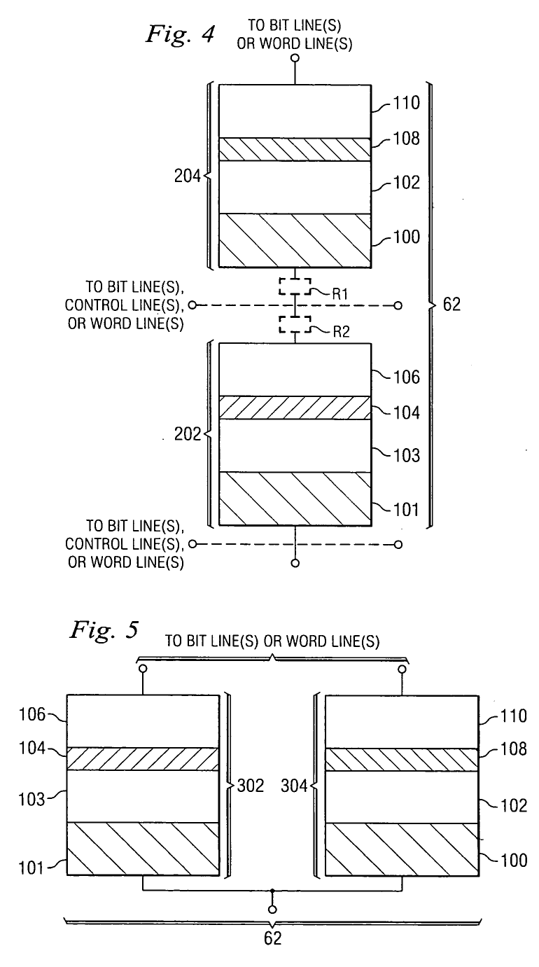

Referring now to FIG. 4, in a second embodiment, a pair of multiple MR sensing MTJ devices 202 and 204 are serially connected to form the MTJ configuration 62. The MTJ device 202 includes a free layer 106, a barrier 104, a pinned layer 103, and an anti-ferromagnetic layer 101. Similarly, the MTJ device 204 includes a free layer 110, a barrier 108, a pinned layer 102, and an anti-ferromagnetic layer 100. The pinned layers 102, 103 may be part of a larger, contiguous ferromagnetic layer, and the anti-ferromagnetic layers 100, 101 may be a part of a larger, contiguous anti-ferromagnetic layer. The embodiment of FIG. 4 operates in the same manner as the embodiment in FIG. 3 except for the writing process. The control lines write to the control lines can induce a magnetic field within the free layers 106 and 110 allowing each free layer 106 and 110 to be written without disturbing the other free layer 106 or 110. One advantage of the MTJ configuration 62 is that a two step writing process may not be required, resulting in an increased programming speed.

In some embodiments, the MTJ configuration 62 may also include one or more resistive elements in series between MTJ devices. For example, in FIG. 4, resistive elements R1 and R2 may be placed in series with MTJ device 202 and MTJ device 204. The resistive elements R1 and R2 would shift the magneto-resistance ratios, but would not change the general operation of the memory cell embodiment. The resistive element can be made from materials such as, for example, a layer of diamond-like carbon (DLC), a layer of Ti/Ta/X, where X is a metal, a layer of Ti/TaN/TiW, and other materials. The material and/or thickness of the resistive element are selected so that the resistive element does not behave as an anti-fuse during programming of the MTJ configuration 62. The resistive element could be formed by chemical vapor deposition (CVD),plasma enhanced chemical vapor deposition (PECVD) electro-chemical deposition, physical vapor deposition, molecular manipulation or any other method that is known by one who is skilled in the art.

Table 2 illustrates the logical binary states of the MTJ configuration cell 62 in FIG. 4. As shown under condition 1, the tunneling resistance can be minimized where the magnetic moments of both ferromagnetic free layers 106 and 110 are in parallel and where they are both parallel with the magnetic moment of the pinned layer 102. Condition 4 demonstrates that a maximum serial resistance can be realized with both free layers 106 and 110 in parallel and anti-parallel to the magnetic moment of the pinned layer 102. Under condition 2 where the magnetic moments of the free layers 106 and 110 are anti-parallel and where free layer 106 is parallel with the pinned layer 102, the serial resistance can be greater than it is in Table 2, condition 1. In condition 4, serial resistance can be slightly lower than the maximum when both free layers 106 and 110 magnetic moments are anti-parallel and the pinned layer 102 is anti-parallel to free layer 106.

TABLE 2

| | Magnetic Moment Direction | | | |
|---|---|---|---|---|
| | Condition | Condition | Condition | |
| Layer | 1 | 2 | 3 | Condition 4 |
| Free Layer 110 | [symbol] | [symbol] | [symbol] | [symbol] |
| Free Layer 106 | [symbol] | [symbol] | [symbol] | [symbol] |
| Pinned Layer | [symbol] | [symbol] | [symbol] | [symbol] |
| Tunneling Resistance | Minimum | | | |
| Barrier 108 (MR ratio | 1 | 1.3 | 1 | 1.3 |
| 30%) | | | | |
| Barrier 104 (MR ratio | 1 | 1 | 1.6 | 1.6 |
| 60%) | | | | |
| Serial Resistance | 2 | 2.3 | 2.6 | 2.9 |

Referring now to FIG. 5, a third embodiment of the MTJ configuration 62 includes two sets of single junction MTJ devices 302 and 304 that are electrically connected in parallel. The MTJ device 302 includes a free layer 106, a barrier 104, a pinned layer 103, and an anti-ferromagnetic layer 101. Similarly, the MTJ device 304 includes a free layer 110, a barrier 108, a pinned layer 102, and an anti-ferromagnetic layer 100. The pinned layers 102, 103 may be part of a larger, contiguous ferromagnetic layer, and the anti-ferromagnetic layers 100, 101 may be a part of a larger, contiguous anti-ferromagnetic layer. The barriers 104, 108 in this case can be assigned different MR ratios. For example, the barrier 108 can have a MR ratio of 25% and the barrier 104 can have a MR ratio of 58%. The embodiment of the multiple level sensing MTJ configuration 62 of FIG. 5 operates in a similar manner to the embodiment in FIG. 4, with the differences identified below. Table 3 shows four kinds of conditions and four different levels of resistance in parallel. Each logical status of the ferromagnetic free layer 106 and ferromagnetic free layer 110 can be distinguished.

TABLE 3

| | Magnetic Moment Direction | | | |
|---|---|---|---|---|
| | Condition | Condition | Condition | |
| Layer | 1 | 2 | 3 | Condition 4 |
| Free Layer 110 | [symbol] | [symbol] | [symbol] | [symbol] |
| Free Layer 106 | [symbol] | [symbol] | [symbol] | [symbol] |
| Pinned Layer | [symbol] | [symbol] | [symbol] | [symbol] |
| Tunneling Resistance | Minimum | | | |
| Barrier 108 | 1 | 1.25 | 1 | 1.25 |
| (MR ratio 25%) | | | | |
| Barrier 104 | 1 | 1 | 1.58 | 1.58 |
| (MR ratio 58%) | | | | |
| Parallel Resistance | 0.500 | 0.556 | 0.612 | 0.698 |

The parallel MTJ configuration 62 provides a more narrow range of magneto-resistances compared to the serial configuration discussed in the previous embodiments. Under condition 1, the tunneling resistance can be at a minimum when the magnetic moments of both ferromagnetic free layers 106 and 110 and the pinned layer 102 are in parallel. Under condition 4, a maximum in serial resistance can be realized with both free layers 106 and 110 parallel, but anti-parallel to the magnetic moment of the pinned layer 102. If the magnetic moments of the free layers 106 and 110 are anti-parallel, as in condition 2, and the free layer 106 is parallel, the serial resistance can be greater than it is in condition 1. Under condition 3, serial resistance can be slightly lower than the maximum when the magnetic moments of both free layers 106 and 110 are anti-parallel and the pinned layer 102 is anti-parallel to free layer 106. A parallel multiple level sensing configuration may be attractive in MRAM designs where larger currents may be supplied or where smaller voltage drops may be desired in the MRAM circuit.

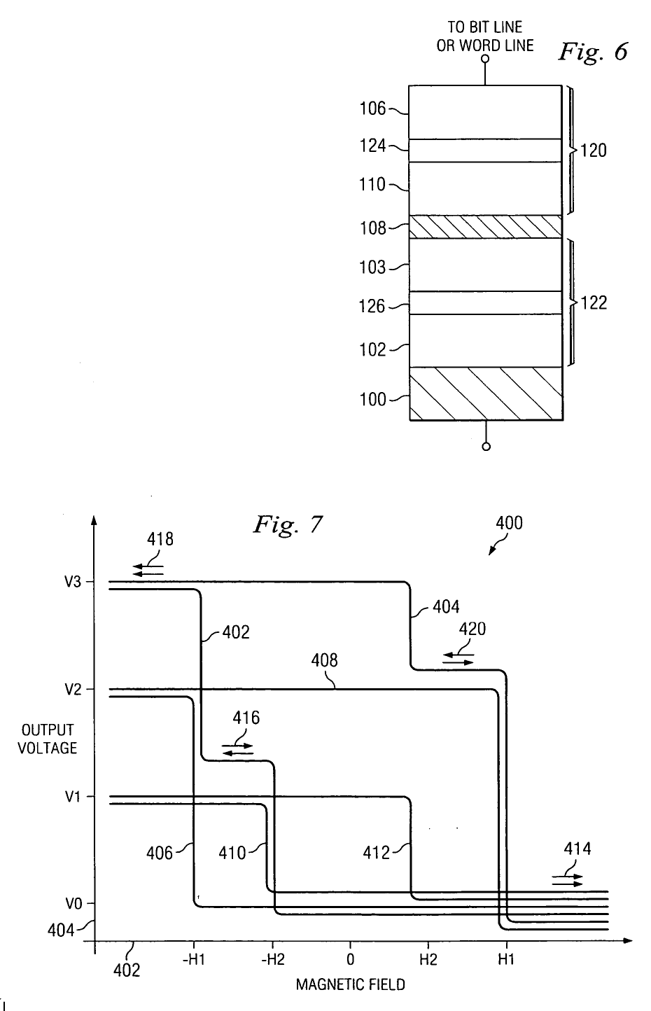

Referring to FIG. 6, in a fourth embodiment of the MTJ configuration 62, a pair of multiple MR sensing MTJ devices can collectively include a synthetic anti-ferromagnetic (SAF) free structure 120, a barrier layer 108, a SAF pinned layer 122, and an anti-ferromagnetic layer 100. The SAF free structure 120 can include two ferromagnetic layers 106 and 110 sandwiching an anti-ferromagnetic exchange layer 124. Also, the SAF pinned layer 122 can include two ferromagnetic layers 103 and 102 sandwiching an anti-ferromagnetic exchange layer 126. The embodiment of FIG. 6 operates in a manner consistent with the embodiment of FIG. 3 except that the SAF layer is an alternative to a single free layer or pinned layer. The SAF layer(s) feature a flux-closed structure that reduces disturbance. Flux-closed structures are described in U.S. Pat. No. 6,166,948, which is hereby incorporated by reference.

Referring now to FIG. 7, a hysteresis curve 400 of the MTJ structure 62 illustrate the voltage, magnetic field strength, and magnetic moments according to some embodiments of the present disclosure. Hysteresis curve 400 represents an embodiment where free magnetic layers 106 and 110 can be controlled by a single bit or control line, such as in FIG. 3. The magnetic fields associated with the two MTJ devices of the MTJ configuration 62 are identified as values H1 and H2, and the output voltages are identified as V0, V1, and V2. In the present example, it does not matter which MTJ device corresponds to the values H1 or H2, as long as H1≢H2. A horizontal axis 402 represents the magnetic field strength, and a vertical axis 404 represents the output voltage over the MTJ structure 62. Pairs of arrows 414, 416, 420 describe directions of magnetic moments in the free magnetic layers 106 and 110, with the upper arrow in the figure corresponding to layer 106 and the lower arrow corresponding to layer 110. A right direction (as shown in the figure) of an arrow indicates the parallel while a left direction of an arrow represents anti-parallel. First and second curves 402 and 404 described by solid lines indicate output voltage over the MTJ structure 62, which could be achieved for the application of various strengths of magnetic. Third and fourth curves 406 and 408 could indicate output voltage over one MTJ device, and the fifth and sixth curves 410 and 412 could represent a voltage output over the other MTJ devices, Superimposing curve 406 on curve 410 and curve 408 over 412 could represent the hysteresis of a series multiple level sensing MTJ structures 62.

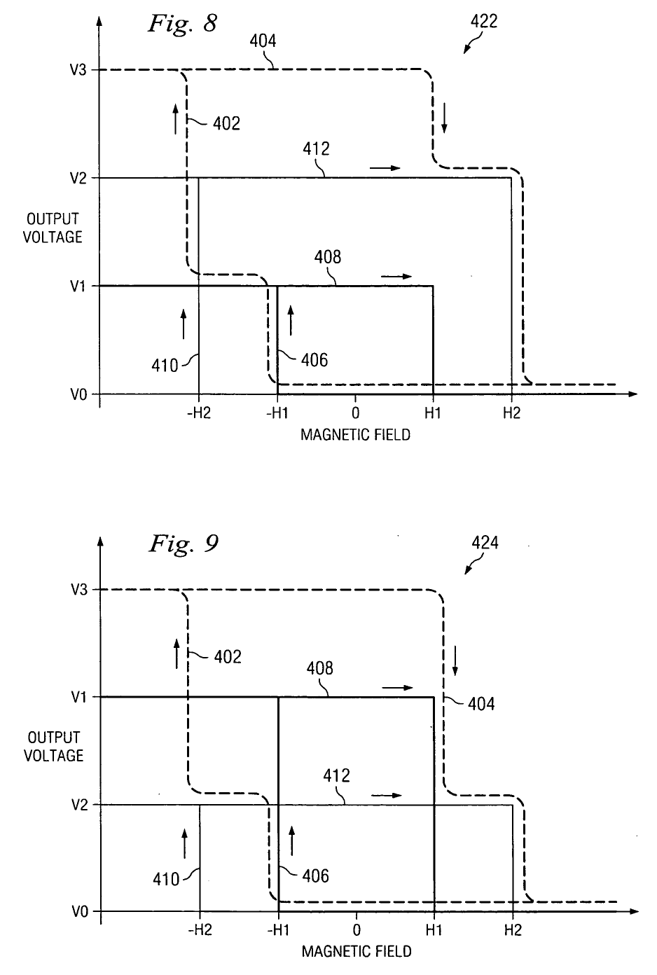

Referring now to FIGS. 8 and 9, hysteresis curves 422 and 424 of the MTJ structure 62 illustrate the voltage, magnetic field strength, and magnetic moments according to other further embodiments of the present disclosure. Hysteresis curves 422, 424 represent further embodiments where free magnetic layers 106 and 110 can be controlled by separate bit lines, such as in FIGS. 3. In these embodiments, magnetic values H1 and H2 can be the same or different. The curve 422 and 424 of FIG. 8 can be associated with multiple free layers 106 and 110 connected to one bit or control line, and the curve 424 is associated with the other MTJ device connected to the other bit line. In FIG. 8, the output voltage V2 is greater than the output voltage V1, while in FIG. 9, the output voltage V1 is greater than the output voltage V2.

Therefore, the multiple level sensing MTJ configuration 62 gives a hysteresis curve 400 indicating at least four different stable levels, which are caused by magnetic directions in the magnetic free layers 106 and 110 as shown by arrows 414-420. Accordingly, the MTJ configuration 62 can memorize at least four bits of information corresponding to the four levels by the multiple MR ratios.

Referring to Table 4, the MTJ configuration 62 can be read by measuring a corresponding output voltage. Referring also to FIGS. 1 and 2, it is understood that the array logic 54 can select a desired memory cell 60 to read four bits of data from the MTJ configuration 62.

TABLE 4

| Output Voltage | Bit States |
|---|---|
| V0 | 00 |
| V1 | 10 |
| V2 | 01 |
| V3 | 11 |

Referring to Table 5, the MTJ configuration 62 can be written to by providing one or more specific magnetic fields. A combined magnetic field can be generated by two currents provided to the MTJ configuration 62, specifically to magnetic free layers 106 and/or 110. The direction of the combined magnetic field can be specified by the directions of the current in the bit line. The combined magnetic field allows directions in free magnetic layers 106 and/or 110 to be switched. A current source is part of the array logic 54 (FIG. 1) and controls the amount and directions of the current.

TABLE 5

| Magnetic Field | Bit States |
|---|---|
| H1 | 00 |
| H1 then -H2 | 10 |
| -H1 then H2 | 01 |
| -H2 | 11 |

Referring also to the embodiments of FIGS. 3 and 6, the magnetic fields associated with the two MTJ devices of the MTJ configuration 62 are identified as values H1 and H2. In the present example, it does not matter which MTJ device corresponds with the values H1 or H2, as long as H1≢H2. To store a logic “00” value in the MTJ configuration 62, a magnetic field, which is greater than or equal to H1 is applied to both magnetic junctions 114 in the parallel. To store a logic “10”, two steps can be carried out. First, a magnetic field greater than or equal to H1 is applied to store the logic “00”, and then a magnetic field between −H2 and −H1 can be applied to switch the direction of the magnetic moments in only one of the layers 106 or 110 (depending on their configuration). To store a logic “11” value, a magnetic field which is less than or equal to −H1 can be applied such that both magnetic junctions are set to the anti-parallel.

To store a logic “01”, two steps can be carried out. First a magnetic field which is less than or equal to −H1 can be applied to store the value “11”, and then a magnetic field between +H2 and +H1 can be applied to switch the direction of the magnetic moments in only one of the layers 106 or 110 (depending on their configuration).

For the embodiments of FIGS. 4 and 5, in which the free layers 106 110 can be controlled by two independent bit lines, the values H1 and H2 can either be the same or set to different values. Furthermore, when two independent bit lines are used, each of the MTJ devices can be individually written with a corresponding bit. The method of writing to a single bit is a subset of the method described above with respect to writing two bits.

According to the above embodiments, the MTJ configuration 62 may not require active silicon-based isolation elements in order to isolate the memory cells in a memory array. The MTJ configuration 62 may be stacked memory elements or even three-dimensionally connected for fabrication on non-planar surfaces, curved, and spherical geometries, increasing device capacity. The MTJ configuration 62 may be fabricated by materials that are novel or non-conventional by semiconductor technologies.

An advantage of using MTJ configurations and configurations with multiple level sensing capabilities is that each MTJ configuration in the above discussed embodiments exhibits its own resistance characteristic due to the differing MR ratios of each MTJ configuration. The MR ratio of each MTJ can be controlled by differing the material or composition of each tunneling barrier 104 and 108. This allows each stacked MTJ configuration 62, as shown in FIG. 3, or the un-stacked configurations of FIGS. 4 and 5 to simultaneously store two bits. The present embodiments of the MTJ configuration 62 have the ability to sense at least four different logical states based on the differing MR ratios, and this allows for a two times increase in memory density within the same or similar area used in a single MTJ configuration.

Based on the illustrated embodiments, one of ordinary skill in the art can easily apply the teachings of the present disclosure to create MTJ configurations that can store greater than two bits with greater than four levels of MR sensing. Likewise, one of ordinary skill in the art can easily apply the teachings of the present disclosure to other semiconductor devices and structures using multiple level sensing with different MR ratio MRAM cells.

1. A magnetic tunnel junction (MTJ) configuration for use in a magnetic memory cell, the configuration comprising:
a first free layer proximate to a first tunneling barrier;
a second free layer proximate to a second tunneling barrier and a pinned layer;
wherein the first free layer is sandwiched between the first and second tunneling layers.

2. The MTJ configuration of claim 1 wherein the first tunneling barrier has a magneto-resistance (MR) ratio that differs from a MR ratio of the second tunneling barrier.

3. The MTJ configuration of claim 1 wherein the first and second free layers comprise a synthetic anti-ferromagnetic structure.

4. The MTJ configuration of claim 1 further comprising:
a third free layer and a third tunneling layer;
wherein the second free layer is sandwiched between the second tunneling layer and the third tunneling layer.

5. The MTJ configuration of claim 1 further comprising
an anti-ferromagnetic layer, wherein the pinned layer is sandwiched between the first tunneling barrier and the anti-ferromagnetic layer.

6. The MTJ configuration of claim 1 wherein the pinned layer is a synthetic anti-ferromagnetic layer.

7. The MTJ configuration of claim 1 wherein the first tunneling barrier is comprised of a different material than the second tunneling barrier.

8. The MTJ configuration of claim 1 wherein the first tunneling barrier is formed from a different processing recipe than the second tunneling barrier.

9. The MTJ configuration of claim 1 wherein at least one of the free layers includes a single magnetic layer.

10. The MTJ configuration of claim 1 wherein at least one of the free layers includes a synthetic anti-ferromagnetic layer.

11. A magnetic memory cell comprising a switching element and a magnetic tunnel junction (MTJ) configuration comprising:
a first MTJ device including a first free layer, a first tunneling barrier, and a first pinned layer;
a second MTJ device including a second free layer, a second tunneling barrier, and a second pinned layer;
a first conductor connecting the first and second MTJ devices;
wherein a first magneto-resistance of the first MTJ device is different from a second magneto-resistance of the second MTJ device.

12. The memory cell of claim 11 wherein the second magneto-resistance is twice of the first magnetic resistance.

13. The memory cell of claim 11 wherein the second MTJ device includes an anti-ferromagnetic material and wherein the first free layer is connected to the anti-ferromagnetic material through the first conductor.

14. The memory cell of claim 11 wherein the MTJ configuration further comprises:
a second conductor connected to the second free layer;
wherein the first conductor connects to the first free layer and
wherein the first and second MTJ devices can be simultaneously written to using the second and first conductors respectively.

15. The memory cell of claim 11 wherein at least one of the free layers includes a spacer sandwiched between two ferromagnetic layers.

16. The memory cell of claim 11 wherein the first tunneling barrier is comprised of a different material than the second tunneling barrier.

17. The memory cell of claim 11 wherein the first tunneling barrier is formed from a different processing recipe than the second tunneling layer.

18. An integrated circuit comprising:
an input/output section;
a plurality of logic circuits connected to the input/output section; and
a plurality of magnetic memory cells connected to the logic circuits, the magnetic memory cells including a transistor and a storage structure including:
a first magnetic junction device including a first free layer, a first tunneling area, and a first pinned layer;
a second magnetic junction device including a second free layer, a second tunneling area, and a second pinned layer; and
a first conductor connected to configure the first and second magnetic junction devices in parallel.

19. The integrated circuit of claim 18 wherein a first magneto-resistance of the first magnetic junction device is different from a second magneto-resistance ratio of the second magnetic junction device.

20. The integrated circuit of claim 18 wherein the second magnetic junction device includes an anti-ferromagnetic material and wherein the first free layer is connected to the anti-ferromagnetic material through the first conductor.

21. The integrated circuit of claim 18 further comprising;
a second conductor connected to the second free layer;
wherein the first conductor connects to the first free layer; and
wherein the first and second magnetic junction devices can be simultaneously written to using the second and first conductors respectively.

22. The integrated circuit of claim 18 wherein at least one of the free layers includes a spacer sandwiched between two ferromagnetic layers.

23. The integrated circuit of claim 22 wherein the spacer comprises a synthetic anti-ferromagnetic material.

24. The integrated circuit of claim 18 wherein the first tunneling barrier is comprised of a different material than the second tunneling barrier.

25. The integrated circuit of claim 18 wherein the first tunneling barrier is formed from a different processing recipe than the second tunneling barrier.

26. The integrated circuit of claim 18 wherein a magneto-resistance ratio of the first tunneling barrier is 50-60% and a magneto-resistance ratio of the second tunneling barrier is 20-30%.
